(19) United States
(12) Patent Application Publication
(10) Pub. No.: US 2025/0346151 A1
(43) Pub. Date: Nov. 13, 2025

(54) ELECTROCHEMICAL IMPEDANCE SPECTROSCOPY DC-LINK PRE-CHARGE CIRCUIT ON ELECTRIC VEHICLES ONBOARD CHARGER

(71) Applicant: STMICROELECTRONICS INTERNATIONAL N.V., Geneva (CH)

(72) Inventors: Filippo BONACCORSO, Catania (IT); Akshay MISRA, Munich (DE)

(21) Appl. No.: 18/662,292

(22) Filed: May 13, 2024

(51) Int. Cl. B60L 58/16; B60L 53/20; G01R 31/389

(52) U.S. Cl. CPC B60L 58/16; B60L 53/20; G01R 31/389; B60L 2210/12; B60L 2210/42; B60L 2270/20

(57) ABSTRACT

Systems, apparatuses, and methods for electrochemical impedance spectroscopy (EIS) for use with batteries are provided, including for a pre-charge circuit on electric vehicles that may be used to generate a stimulus signal for EIS analysis of one or more batteries. An exemplary system may comprise a battery, a pre-charge circuitry, and EIS circuitry. The pre-charge circuitry comprising an inverse buck circuitry with a first capacitor and configured to limit an inrush current during loads connection, which includes charging the first capacitor with a periodic waveform. The EIS circuitry receives the periodic waveform and transmits it as a stimulus signal to the battery. The EIS circuitry receives a response signal from the battery in response to the stimulus signal and generates an impedance of the battery based on the response signal.

### TECHNOLOGICAL FIELD

Example embodiments of the present disclosure relate generally to systems, apparatuses, and methods for electrochemical impedance spectroscopy (EIS) for use with batteries, and particularly for a DC-link pre-charge circuit on electric vehicles that may be used to generate a stimulus signal for EIS analysis of one or more batteries.

### BACKGROUND

Batteries are increasingly being used in a myriad of applications, including vehicles. These vehicles include many systems, including batteries and an onboard charger to charge the batteries.

Electrochemical impedance spectroscopy (EIS) may be used to generate information for determining a state of health of batteries. The state of health of a battery may indicate if a battery is healthy or aged, which may be used to prevent battery damage or determine when a battery should no longer be used. EIS is also used for determining the state of charge or the internal temperature of the batteries.

The inventors have identified numerous areas of improvement in the existing technologies and processes, which are the subjects of embodiments described herein. Through applied effort, ingenuity, and innovation, many of these deficiencies, challenges, and problems have been solved by developing solutions that are included in embodiments of the present disclosure, some examples of which are described in detail herein.

### BRIEF SUMMARY

Various embodiments described herein relate to systems, apparatuses, and methods for electrochemical impedance spectroscopy (EIS) for use with batteries, and particularly for a DC-link pre-charge circuit that may be used to generate a stimulus signal for EIS analysis of one or more batteries.

In accordance with some embodiments of the present disclosure, an example system is provided. The system may comprise: at least one battery; a pre-charge circuitry comprising an inverse buck circuitry, wherein the inverse buck circuitry comprises a first capacitor, and wherein the pre-charge circuitry is configured to limit an inrush current during charging of the at least one battery, including charging the first capacitor with a periodic waveform; an EIS circuitry electrically connected to the pre-charge circuitry to receive the periodic waveform and to transmit the periodic waveform as a stimulus signal to the at least one battery; wherein the EIS circuitry is further configured to receive a response signal from the at least one battery in response to the stimulus signal; and wherein the EIS circuitry is further configured to measure an impedance of the battery based on the response signal.

In some embodiments, the stimulus signal is comprised of one or more triangular waveforms.

In some embodiments, the stimulus signal is comprised of at least three phases, including a beginning phase, a central phase, and a final phase, wherein the periodic waveform is different in of the at least three phases.

In some embodiments, the EIS circuitry is configured to receive the periodic waveform during battery charging and battery discharging.

In some embodiments, a battery management system, wherein the battery management system is configured to generate a state of health of the at least one battery based on the impedance.

In some embodiments, the EIS circuitry is further configured to generate at least one additional signal to superimpose on the periodic waveform of the stimulus signal.

In some embodiments, the at least one additional signal comprises a first frequency that is different from the frequency of the periodic waveform.

In some embodiments, the pre-charge circuitry is located in a traction inverter, an on-board charge, or an auxiliary DC/DC.

In some embodiments, the EIS circuitry is included in an integrated circuit.

In some embodiments, the system is a vehicle.

In accordance with some embodiments of the present disclosure, an example method is provided. The method comprising generating, with a pre-charge circuitry comprising an inverse buck circuitry, a periodic waveform to charge a first capacitor, wherein the inverse buck circuitry comprises the first capacitor, and wherein the pre-charge circuitry is configured to limit an inrush current during charging of at least one battery; receiving the periodic waveform at an EIS circuitry; transmitting, by the EIS circuitry to the at least one battery, the periodic waveform as a stimulus signal; receiving, at the EIS circuitry from the at least one battery, a response signal based on the stimulus signal; and measuring an impedance of the at least one battery based on the response signal.

In some embodiments, the stimulus signal is comprised of one or more triangular waveforms.

In some embodiments, the stimulus signal is comprised of at least three phases, including a beginning phase, a central phase, and a final phase, wherein the periodic waveform is different in of the at least three phases.

In some embodiments, receiving the periodic waveform at an EIS circuitry is during battery charging and battery discharging.

In some embodiments, the method further comprises generating, by a battery management system, a state of health of the at least one battery based on the impedance.

In some embodiments, the method further comprises generating, by the EIS circuitry, at least one additional signal to superimpose on the periodic waveform of the stimulus signal.

In some embodiments, the at least one additional signal comprises a first frequency that is different from the frequency of the periodic waveform.

In some embodiments, the pre-charge circuitry is located in a traction inverter, an on-board charge, or an auxiliary DC/DC.

In some embodiments, the EIS circuitry is included in an integrated circuit.

In some embodiments, the pre-charge circuitry, the EIS circuitry, and the at least one battery are in a vehicle.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF SUMMARY OF THE DRAWINGS

Having thus described certain example embodiments of the present disclosure in general terms, reference will now be made to the accompanying drawings, which are not necessarily drawn to scale, and wherein:

FIG. 1 illustrates an example battery and equivalent circuit in accordance with one or more embodiments of the present disclosure;

FIG. 2 illustrates an exemplary EIS circuitry in accordance with one or more embodiments of the present disclosure;

FIG. 3 illustrates an exemplary equivalent circuitry and associated impedance measurements in accordance with one or more embodiments of the present disclosure;

FIG. 4 illustrates an exemplary graph of impedance measurements in accordance with one or more embodiments of the present disclosure;

FIGS. 5A-5C illustrate exemplary circuit diagrams of pre-charge circuits in accordance with one or more embodiments of the present disclosure;

FIG. 6A illustrates a block diagram of an exemplary vehicle in accordance with one or more embodiments of the present disclosure;

FIG. 6B illustrates a diagram of an exemplary traction inverter in accordance with one or more embodiments of the present disclosure;

FIG. 6C illustrates a diagram of an exemplary auxiliary DC/DC in accordance with one or more embodiments of the present disclosure;

FIG. 7 illustrates an exemplary inverse buck circuitry in accordance with one or more embodiments of the present disclosure;

FIG. 8 illustrates an exemplary pre-charge circuitry in accordance with one or more embodiments of the present disclosure;

FIG. 9 illustrates an exemplary first signal in accordance with one or more embodiments of the present disclosure;

FIG. 10 illustrates an exemplary flowchart of a first set of operations for determining an impedance in accordance with one or more embodiments of the present disclosure; and

FIG. 11 illustrates an exemplary device in accordance with one or more embodiments of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in various embodiments,” “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments or it may be excluded.

The use of the term “circuitry” as used herein with respect to components of a system or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communications circuitry, input/output circuitry, and the like. In some embodiments, other elements may provide or supplement the functionality of particular circuitry.

### Overview

Various embodiments of the present disclosure are directed to improved systems, apparatuses, and methods for electrochemical impedance spectroscopy (EIS) for use with batteries, and particularly for a DC-link pre-charge circuit that may be used to generate a stimulus signal for EIS analysis of one or more batteries.

The present disclosure provides for utilizing current electric vehicle (EV) architecture to generate an excitation signal to perform battery EIS. Electric vehicles (EVs) use batteries for power storage. Battery management systems (BMS) are used to monitor the health of batteries. Other devices and appliances aside from EVs also use batteries, such as consumer electronics, battery storage systems, and the like. While this disclosure may refer to an EV it will be readily appreciated that other types of vehicles, systems, and/or devices are contemplated herein.

Electrochemical Impedance Spectroscopy (EIS) may be used to estimate a State of Health (SoH), State of Charge (SoC), and/or Inner Cell Temeprature of a battery. A battery's state of health worsens with usage of charge/discharge cycles. A battery's state of health may indicate if a battery is healthy or aged. Such indications may assist in preventing battery damage, explosions, and/or advising when it is time for a new battery. A manner of determining the state of health of a battery is with electrochemical impedance spectroscopy (EIS). EIS evaluates a battery chemistry of a battery focusing on the equivalent circuit model. In this equivalent circuit model the battery may be modeled as a voltage source and an impedance. EIS uses impedance measurements based on response signals generated by a battery in response to a stimulus signal. EIS may be performed during both charging and discharging.

In conventional EIS measurements system there is an excitation circuitry that generates a stimulus signal to stimulate the battery for generating a response signal. Such conventional excitation signals are powered by a power source, such as a battery, and thus use the power source's energy to generate the stimulus signal. This is an additional energy usage by generating a stimulus signal anew. This may also require additional circuitry than compared to embodiments of the present disclosure. Embodiments in accordance with the present disclosure may utilize a waveform produced by pre-charge circuitry as a stimulus signal to provide to the battery. Thus the energy, circuitry, and cost associated and/or required by conventional EIS systems may be reduced. Moreover, the present disclosure utilizes energy associated with pre-charge circuit that would otherwise be waste as a stimulus signal.

Impedance measurements are based on the current and voltage of the response signal. Measurements of the voltage V(t) and current I(t) are used to evaluate the impedance Z(jω) of a battery. In various embodiments, the battery is comprised of multiple battery cells, and impedance may be measured at each cell or collectively.

In an EV architecture, the DC-link pre-charge circuitry may be used to generate a stimulus signal that is transmitted to at least one battery to generate a response signal. The response signal may be used for EIS, which is used to determine, among other things, a state of health of the at least one battery.

The DC-Link pre-charge circuitry may be included in the onboard charger, the traction inverter, the auxiliary DC/DC, or another system or subsystem of a vehicle. The pre-charge circuitry may generate power that are used to pre-charge a capacitor(s) connected to any load. Pre-charging uses a switch to close in on a circuit that will charge a DC-link capacitor to a voltage slowly before providing a full voltage for a load. Electronic systems can be damaged by inrush currents, particularly in high voltage systems with downstream capacitance. Inrush currents can cause significant stress or damage to all components in the system, including batteries. Pre-charge circuits may be used to protect these downstream systems by limiting inrush current. Pre-charge circuits limit inrush current by slowly charging downstream capacitances until the voltage level rises close to the source voltage. After slowing down an inrush current one or more switches may open or close to close a power source to a load. The use of pre-charge circuits increases the lifespan of electric components and batteries.

Various embodiments may use the discharging of the DC-Link capacitor to provide an excitation signal to the EIS circuitry. In various embodiments, a processor (e.g., MCU) may also be powered by the pre-charge DC-Link capacitor and perform wave shaping to generate a stimulus signal or excitation signal used in the EIS circuitry. The EIS circuitry may be physically located close to the batteries of an electric vehicle while pre-charge circuitry generating the stimulus signal may be located further away. The close location of the EIS circuitry may allow for faster generation of EIS measurements.

### Exemplary Systems, Apparatuses, and Methods

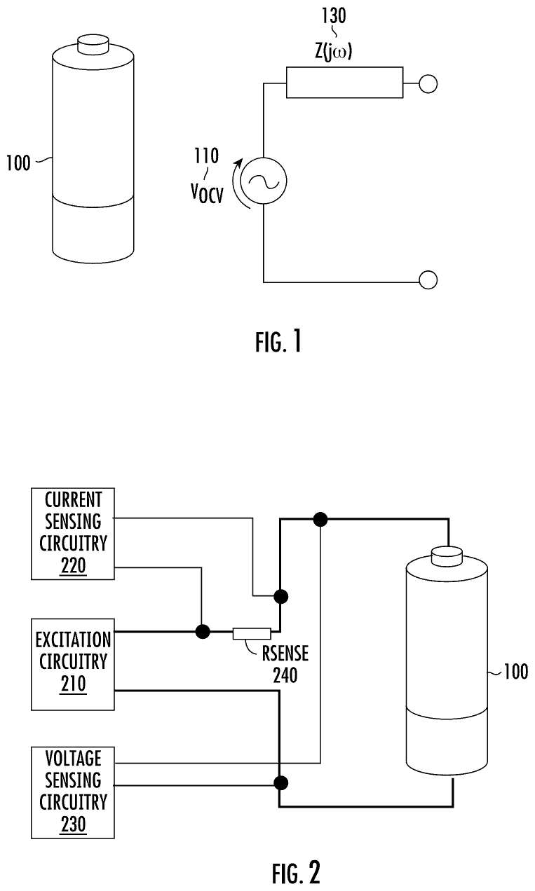

FIG. 1 illustrates an example battery and equivalent circuit in accordance with one or more embodiments of the present disclosure. A battery 100 has a battery chemistry that is associated with an equivalent circuit comprised of a voltage source 110, a current, and an impedance 130. The impedance 130 may be measured based on the voltage of voltage source 110 and current.

EIS measurements may be performed during both charging and discharging of a battery. A voltage measurement may be V(t) of the equivalent voltage source 110, which is illustrated as an open circuit voltage V_{OCV}. A current measurement may be I(t) of the equivalent current through an impedance 130 Z(jω). Measurements of the voltage V(t) and current I(t) may be used to evaluate the impedance 130 Z(jω) of the battery 100.

While battery 100 is illustrated as a single battery, a battery 100 may include multiple battery cells. An impedance 130 may be measured at each battery cell, all battery cells collectively, or as one or more groupings of multiple battery cells.

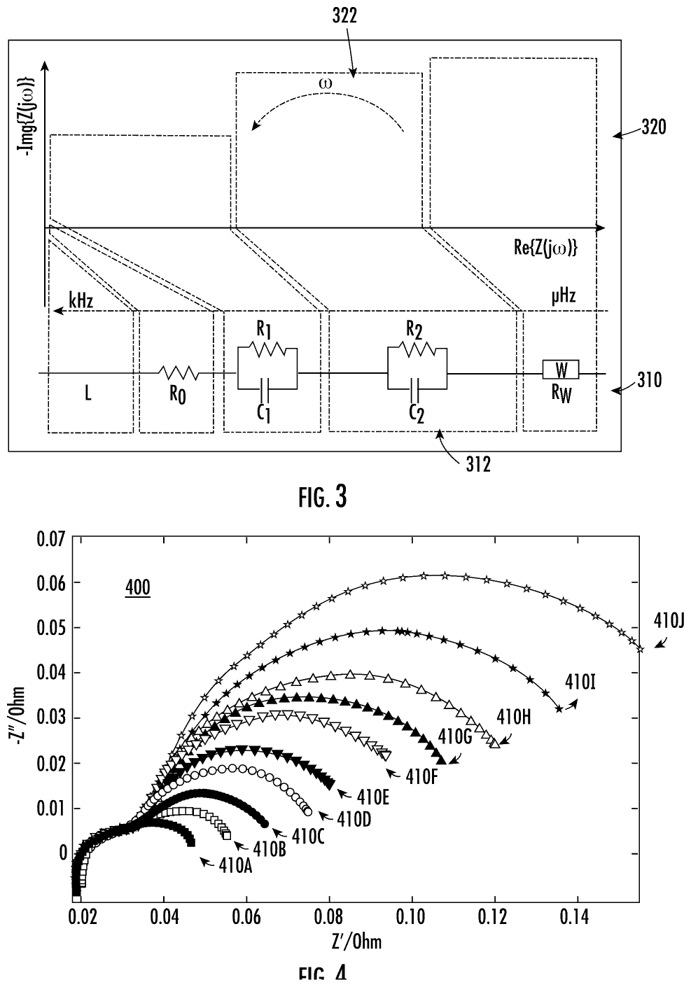

FIG. 2 illustrates an exemplary EIS circuitry in accordance with one or more embodiments of the present disclosure. The EIS circuitry may comprise, among other things, an excitation circuitry 210, a current sensing circuitry 220, a voltage sensing circuitry 230, and a sensing resistor 240. The EIS circuitry may be electrically connected to at least one battery 100.

The EIS circuitry includes multiple analog circuitry and/or circuitry components to minimize the digital computation required. In various embodiments, the EIS circuitry also includes an EIS processor in addition to the analog circuits. The EIS processor (e.g., an MCU) may interface with a battery management system (BMS).

The EIS circuitry measures current and voltage of a response of the battery to a stimulus signal. The stimulus signal is generated by an excitation circuitry 210. In various embodiments, the stimulus signal is a current and, in association with the current, a voltage is the response.

The excitation circuitry 210 generates the stimulus signal and provides it to the battery 100 and a response signal is measured for both current and voltage. The voltage and current measurements may be synchronously acquired for use in generating one or more signals for generating an impedance 130. The current is measured across a sensing resistor 240, which is illustrated as RSENSE 240. The current is measured with current sensing circuitry 220 to generate a current signal. The voltage is measured based on the stimulus signal and the response signal. The voltage is measured with voltage sensing circuitry 230 to generate a voltage signal. These voltage and current measurements are used to determine impedance.

FIG. 3 illustrates an exemplary equivalent circuitry and associated impedance measurements in accordance with one or more embodiments of the present disclosure. Various portions of a battery (e.g., chemical and/or physical portions or aspects) may have different electrical component equivalents. It will be appreciated that FIG. 3 is illustrative and may not be to size and/or various portions of the impedance may be associated with other models that include one or more electrical components. These different electrical component equivalents are associated with the impedance measurements. The exemplary equivalent circuitry 310 associated with the impedance 130 of a battery 100 varies with frequency. For example, and going from a frequency with a longer time period (e.g., kHz) to a frequency with a short time period (e.g., μHz), the equivalent circuitry of the impedance may be an inductor (L), a first resistor (R₀), a second resistor (R₁) in parallel with a first capacitor (C₁), a third resistor (R₂) in parallel with a second capacitor (C₂), and a resistor (R_{W}), which is referred to in FIG. 3 with reference number 312. For EIS measurements, the values of the overall impedance is used as these values change as a battery ages or is damaged.

The top portion of FIG. 3 is a graph 320 of the positive real portion of an impedance on the x-axis and a negative imaginary portion of the impedance on the y-axis. The y-axis using the negative imaginary portion of the impedance 322 is due to the capacitor in the equivalent model as capacitors have a negative imaginary impedance. The change in the impedance 322 over time may be graphed, which may demonstrate how the impedance 322 changes with age and/or damage.

FIG. 4 illustrates an exemplary graph of impedance measurements in accordance with one or more embodiments of the present disclosure. A graph 400 includes measurements of the impedance, including impedance 322, of a battery 100 over time after different numbers of cycles.

The graph 400 is of a Nyquist diagram that includes 10 impedances as measured for a battery 100 after 10 periods of 100 cycles.

The first impedance 410A is after 100 cycles.

The second impedance 410B is after 200 cycles.

The third impedance 410C is after 300 cycles.

The fourth impedance 410D is after 400 cycles.

The fifth impedance 410E is after 500 cycles.

The sixth impedance 410F is after 600 cycles.

The seventh impedance 410G is after 700 cycles.

The eighth impedance 410H is after 800 cycles.

The ninth impedance 4101 is after 900 cycles.

The tenth impedance 410J is after 1000 cycles.

As illustrated in FIG. 4, the aging of a battery 100 through cycling increases the impedance 322 from 100 cycles (e.g., 410A) to 1000 cycles (e.g., 410J). Specifically, the arc of impedance 322, which is the second arc, widens with aging. As illustrated, the impedance is measured at a plurality of frequencies, such as with a frequency sweep. In various embodiments, the frequency sweep may be performed by varying the frequency of the stimulus signal provided to a battery 100. By determining impedance measurements the state of health of the battery may be determined.

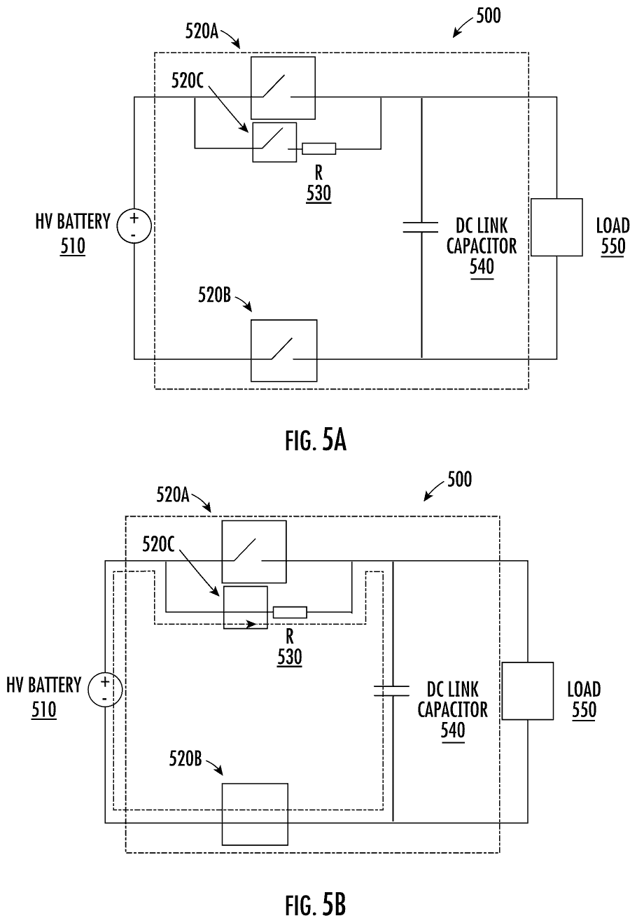

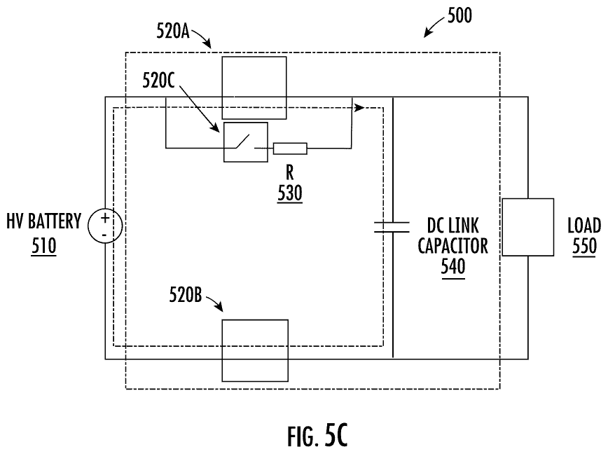

FIGS. 5A-5C illustrate exemplary circuit diagrams of pre-charge circuits in accordance with one or more embodiments of the present disclosure. The exemplary circuit diagrams of pre-charge circuits FIGS. 5A-5C are illustrative of how switching of one or more contactors, switches, or the like may charge a pre-charge capacitor. It will be appreciated that various embodiments, such as described herein, may include additional circuitry and/or electrical components.

Various embodiments of a pre-charge circuit 500 may include, among other things, an HV positive contactor 520A, an HV negative contactor 520B, a pre-charge contactor 520C, a pre-charge resistor 530, and a DC link capacitor 540. A battery 510 and a load 550 are connected to the pre-charge circuit 500. FIGS. 5A-5C illustrate pre-charge circuitry 500 utilized in various embodiments to limit inrush current, but it will be readily appreciated that pre-charge circuits 500 may include additional electrical circuitry and/or components, including as described herein.

FIGS. 5A-5C illustrate turning on and off contactors to limit inrush current provided to a load. For example, a pre-charge resistor 530 is used to limit the inrush current during application of the battery's 510 voltage. By operating contactors 520 or switches, an inrush resistor 530 may be used to limit current to a load 550, such as when starting a load 550 of a motor. Once voltage at a DC link capacitor 540 is to a desired, and safer, level, one or more of the contactors 520 may be operated to open and/or close.

FIG. 5A has the HV positive contactor 520A, HV negative contactor 520B, and pre-charge contactor 520C open. Thus no current flows from the battery to the pre-charge circuit 500.

FIG. 5B has the HV positive contactor 520A open and the HV negative contactor 520B and pre-charge contactor 520C closed. Thus a current flows from the battery 510 through the pre-charge contactor 520C, through the DC link capacitor 540, and through the HV negative contactor 520C. The pre-charge resistor 530 is in the current path to limit the amount of current provided to the DC link capacitor 540 and/or the load 550. The pre-charge contactor 530C may remain closed until the voltage at the DC link capacitor 540 is charged with a first voltage from the current provided by the battery 510. The DC link capacitor 640 is thus charged over time at a lower current than if the pre-charge resistor 630 was not in the circuit. In various embodiments, the contactors may be opened or closed with one or more duty cycles.

FIG. 5C has the HV positive contactor 520A and the HV negative contactor 520B closed and the pre-charge contactor 520C open. Thus the pre-charge resistor 530 is not in the current path. If a load 550 is not connected, then the DC link capacitor 540 will be charged by the current from the battery 510. This may allow for the current of the battery 510 to be applied to the DC link capacitor 540 and/or the load 550, which would occur after the DC-link capacitor 540 has been charged.

In various embodiments, pre-charge circuit (e.g., 500) may be used in an on-board charger, traction inverter, auxiliary DC/DC or the like of a vehicle (e.g., electric vehicle, hybrid vehicle, etc.).

In various embodiments, the energy from charging (or discharging) of the DC link capacitor 540 may be used by EIS circuitry for a stimulus signal.

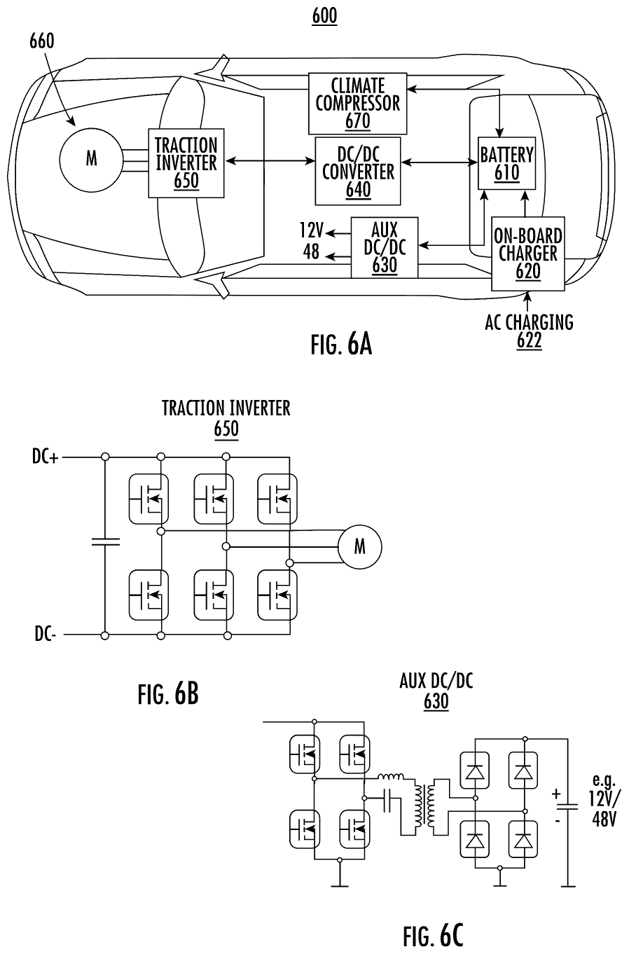

FIG. 6A illustrates a block diagram of an exemplary vehicle in accordance with one or more embodiments of the present disclosure. The vehicle 600 may include one or more systems and/or subsystems, such as a battery 610, an on-board charger 620, AC charging 622, auxiliary (aux) DC/DC 630, DC/DC converter 640, traction inverter 650, and motor 660. In various embodiments the vehicle 600 may include additional systems and/or subsystems, such as a climate compressor 670. Each of these systems and/or subsystems may include one or more related circuitries.

In various embodiments, the battery 610 may include a battery management system. The battery management system may include EIS circuitry, including excitation circuitry 210, current sensing circuitry 220, voltage sensing circuitry 230, and a resistor RSENSE 240. The EIS circuitry may also include an EIS processor to generate one or more output signals based on a response signal received from a battery (e.g., battery cell, group of battery cells, battery pack, etc.). In various embodiments, the excitation circuitry 210 may be electrically connected to one or more other systems and/or subsystems of the vehicle 600, such as to receive a signal from the pre-charge circuitry. The excitation circuitry 210 may receive this signal and provide it to a battery as a stimulus signal to generate a response signal from the battery based on, among other things, the chemistry of the battery. In various embodiments, the excitation circuitry may direct pass through the signal received from the pre-charge circuitry as the stimulus signal. Additionally or alternatively, the excitation circuitry 210 may adjust or condition the signal for generating a stimulus signal, such as use one or more filters to remove one or more frequencies not desired (e.g., a low-pass filter). In various embodiments, excitation circuitry of an EIS circuitry may be omitted as the stimulus signal provided to the battery may be provided by the pre-charge circuitry.

The on-board charger 620 may receive energy from an AC charging 622 to provide energy to the battery 610. The battery 610 may store energy and provide it to other systems and/or subsystems. For example, the battery 610 may provide energy to the aux dc/dc 630, which may convert the DC energy of the battery 610 from a first voltage (e.g., 400 V) to one or more additional voltages (e.g., 12 V, 48 V, etc.) for use by other systems, subsystems, and/or users of the vehicle 600. The battery 610 may provide energy to a DC/DC converter 640 may change the battery 610 voltage to a second voltage that may be used by a traction inverter 650. The traction inverter 650. The traction inverter 650 may convert the second DC voltage from the DC/DC converter 640 to an AC voltage that may be provided to a motor 660 to operate the motor 660. The battery 610 may also provide energy to one or more systems and/or subsystems of the vehicle, such as a climate compressor 670 that may be associated with the vehicle's HVAC system.

Various embodiments of the DC-link pre-charge circuit may be used in a vehicle 600. For example, a pre-charge circuit may be located in an on-board charger 620, an aux dc/dc 630, a traction inverter 640, or the like. In various embodiments, the pre-charge circuit may include an inverse buck circuitry. In various embodiments, the pre-charge circuit may be located in or on an integrated circuit, such a battery management system integrated circuit.

FIG. 6B illustrates a diagram of an exemplary traction inverter in accordance with one or more embodiments of the present disclosure. In various embodiments the traction inverter 650 may include, among other things, one or more switching circuitry (e.g., FETs, diodes, etc.) and one or more capacitors. Such capacitors may be used for use with the pre-charge circuit.

FIG. 6C illustrates a diagram of an exemplary auxiliary DC/DC in accordance with one or more embodiments of the present disclosure. In various embodiments the aux DC/DC 630 may include, among other things, one or more switching circuitry (e.g., FETs, diodes, etc.) and one or more capacitors. Such capacitors may be used for use with the pre-charge circuit.

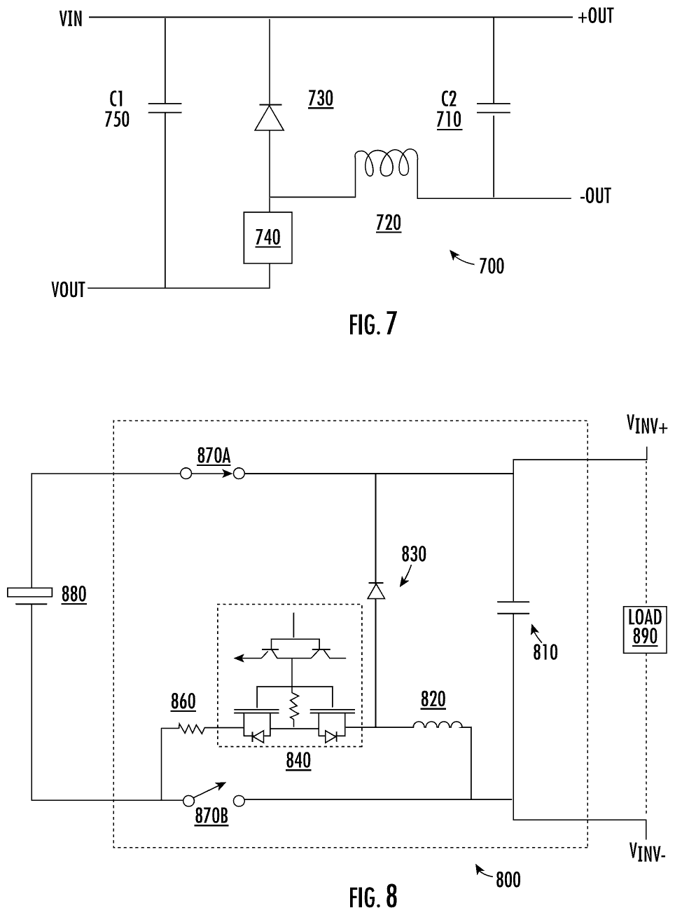

FIG. 7 illustrates an exemplary inverse buck circuitry in accordance with one or more embodiments of the present disclosure. The inverse buck circuitry 700 may contain multiple capacitors (e.g., 710, 750), an inductor, 720, a diode, 730, and switching circuitry 740 (e.g., FET, MOSFET, and the like). In various embodiments the switching circuitry 740 may a MOSFET on the low side of the inverse buck circuitry 700. In various embodiments, the pre-charge circuitry 500 may utilize an inverse buck circuitry 700 instead, or in addition to, a resistor 530 as illustrated in FIGS. 5A-5C. The inverse buck circuitry 700 may be used to charge a DC link capacitor or a capacitor (e.g., 710) of the inverse buck circuitry 700 may be the DC link capacitor.

In various embodiments, operation of the inverse buck circuitry 700 of a pre-charge circuit may raise a voltage of the DC link capacitor. For example, a battery may be connected across the VIN and VOUT terminals as an input into the inverse buck circuitry 700 to generate an output across the +OUT and −OUT terminals. In various embodiments, the voltage of a battery that may be 100 V, 400 V, etc. In various embodiments, the inverse buck circuitry may be integrated into or a part of the various portions of the vehicle 600, such as in the on-board charge 620, traction inventor 650, aux dc/dc 630, etc.

FIG. 8 illustrates an exemplary pre-charge circuitry in accordance with one or more embodiments of the present disclosure. The pre-charge circuitry 800 may include a DC link capacitor 810, an inductor 820, one or more diodes (e.g., 830), switching circuitry 840, one or more resistors (860), a first contactor 870A, a second contactor 870B. The pre-charge circuitry 800 may be electrically connected to a battery 880, such as electrically connecting the positive terminal of battery 880 to the first contactor 870A and electrically connecting the negative terminal of battery 880 to the second contactor 870B. A load 890 may be electrically connected across between a VINV+ terminal and a VIN− terminal of the pre-charge circuitry 800.

In operation, both the first contactor 870A and the second contactor 870B may be in an open state. The first contactor 870A may close and the switching circuitry 840 may be operated to cause a current to flow and charge the DC link capacitor 810. The switching circuitry 840 may be operated to vary the current, such as by using one or more duty cycles, which may cause the current to and/or through the dc-link capacitor 810 to be shaped. The switching circuitry 840 may receive one or more control signals, such as from a processor, to operate the switching circuitry 840. Once the DC link capacitor 810 is charged, the second contactor 870B may close and the current to the load may avoid the inverse buck circuitry of the pre-charge circuitry 800.

In various embodiments of a vehicle, the pre-charge circuitry may operate when the vehicle starts or when an ignition is started. In various embodiments, the pre-charge circuitry may protect one or more systems and/or subsystems of a vehicle, such as from an electric pulse of an inrush current that may have a high transient.

In various embodiments, the pre-charge circuitry 800 may be included in an integrated circuit, such as a battery management IC. Alternatively or additionally, the pre-charge circuitry including an inverse buck may be integrated into or a part of the various portions of the electric vehicle, such as in the onboard charger circuitry, traction inventor circuitry, the auxiliary DC/DC circuitry, etc.

In various embodiments, as the DC-link capacitor is charged (or discharged), the current may be used as or used to generate a first signal. The first signal may be provided to an EIS circuitry, which may generate a stimulus signal based on the first signal. In various embodiments, the first signal may be the stimulus signal provided to the battery to generate a response signal.

FIG. 9 illustrates an illustrates an exemplary first signal in accordance with one or more embodiments of the present disclosure. In various embodiments, a first signal 900 may be generated by pre-charge circuitry. The first signal 900 may be provided to the EIS circuitry, particularly the excitation circuitry 210. The EIS circuitry may use the first signal 900 as a stimulus signal provided to a battery 100. In various embodiments the EIS circuitry may omit excitation circuitry. Alternatively, in various embodiments, the first signal 900 may be adjusted and/or modified by the excitation circuitry to generate the stimulus signal. The first signal generated by the pre-charge circuitry may be used to excite a battery to generate a response signal.

The first signal may be a triangular or ramp waveform. In various embodiments, the triangular waveform may comprise three phases, a beginning phase 910, a central phase 920, and a final phase 930. A triangle or ramp waveform may be used due to charging the DC link capacitor from zero to a first voltage. The beginning phase 910 may have a slow switching frequency. The central phase 920 may have a high switching frequency. The final phase 930 may have a slow switching frequency. In various embodiments, only one or two of the phases may be used for generating the stimulus signal.

In various embodiments the pre-charge circuitry, such as switching circuitry of the pre-charge circuitry, may be controlled to shape the waveform. For example, a processor may control a duty cycle of the switching circuitry (e.g., one or more MOSFETS, etc.) to control current flow to a DC-link capacitor. By controlling the pre-charge circuitry, the pre-charge circuitry may superimpose a frequency that is desired to be measured for an EIS measurement on the waveform of the first signal. Alternatively and/or additionally, in various embodiments, an excitation circuitry of the EIS circuitry may superimpose one or more additional waveforms at various frequencies on the first signal to generate a stimulus signal. For example, one or more FETS in an excitation circuitry may be switched on or off as a switch. Various embodiments may include square waves, sine waves, and the like imposed on the waveform. These superimposed signals with different frequencies may allow for exciting the battery at different frequencies and/or frequency ranges.

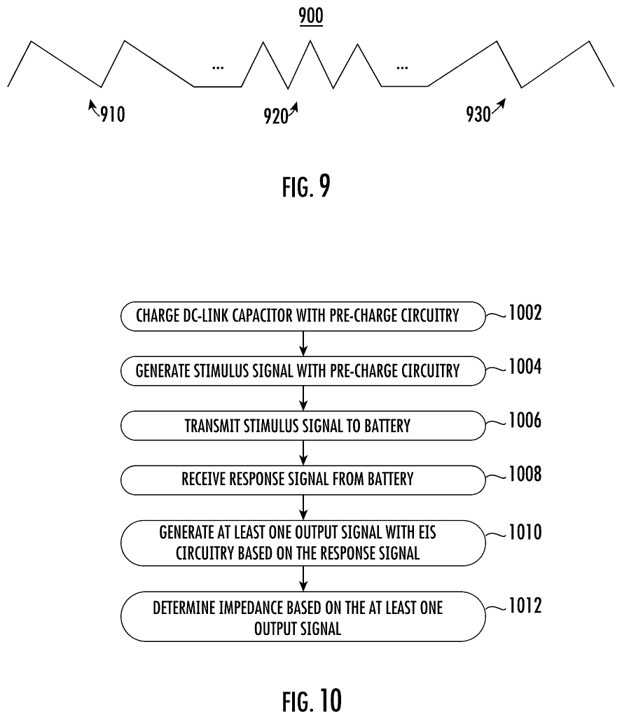

FIG. 10 illustrates an exemplary flowchart of a set of operations for determining an impedance in accordance with one or more embodiments of the present disclosure.

At operation 1002, charge DC-link capacitor with pre-charge circuitry. In various embodiments, pre-charge circuitry may be operated to charge a DC-link capacitor. The DC-link capacitor may be charged by closing one or more contactors of the pre-charge circuitry and/or controlling switching circuitry of the pre-charge circuitry.

At operation 1004, generate stimulus signal with pre-charge circuitry. While charging (or discharging) the DC-link capacitor a stimulus signal may be generated by controlling switching circuitry of the pre-charge circuitry. By operating the switching circuitry to, among other things, open and/or close a stimulus signal may be generated.

In various embodiments, the pre-charge circuitry may generate a first signal that may be transmitted to EIS circuitry as described herein. It will be appreciated for the exemplary operations of this flowchart that the EIS circuitry will receive the stimulus signal generated at operation 1004 and pass it through to a battery.

At operation 1006, transmit stimulus signal to battery. The pre-charge circuitry may generate the stimulus signal and then transmit the stimulus signal to EIS circuitry, which may transmit the stimulus signal to a battery. Alternatively, the pre-charge circuitry may transmit the stimulus signal to the battery without transmitting it to the EIS circuitry.

At operation 1008, receive response signal from battery. A response signal is received by the EIS circuitry from the battery. The response signal 214 is in response to the stimulus signal provided to the battery. The response signal may be based on the stimulus signal but will be adjusted based on the battery, such as based on the battery chemistry of the battery.

At operation 1010, generate at least one output signal with EIS circuitry based on the response signal. The EIS circuitry receives the response signal and may generate a current signal and a voltage signal based on the response signal.

A current sensing circuitry 220 of the EIS circuitry may generate the current signal based on the response signal. The current signal is based on the current of the response signal measured across a sensing resistor 240, which may generate a current signal that is proportional to the current measured. A voltage sensing circuitry 230 may generate the voltage signal based on the response signal and the stimulus signal. A voltage sensing circuitry 230 of the EIS circuitry may generate a voltage signal based on the response signal 214 and the stimulus signal 212. The voltage signal is based on the voltage measured between these two signals, which may generate a voltage signal that is proportional to the voltage measured. Based on the current signal and the voltage signal, the EIS circuitry may generate at least one output signal. In various embodiments the at least one output signal may include one or more of a phase signal, an amplitude signal, or a phase and amplitude signal. Such output signals may be signals that are proportional to a phase, amplitude, and/or amplitude and phase of an impedance.

At operation 1012, determine impedance based on the at least one output signal. The at least one output signal(s) may be provided to a battery management system that may determine or measure an impedance based on the at least one output signals. In various embodiments, the at least one output signals are proportional to the phase, amplitude, and/or amplitude and phase of an impedance. The battery management system may, for example, use a look-up table to determine or measure an impedance value associated with the at least one output signal. In various embodiments, multiple output signals are generated via multiple stimulus signals, including from stimulus signals at varying frequencies. For example, one or more stimulus signals may perform a frequency sweep for stimulated the battery 100.

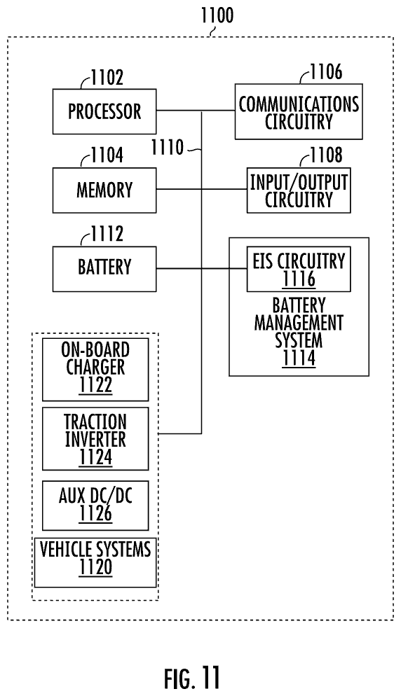

FIG. 11 illustrates an exemplary device in accordance with one or more embodiments of the present disclosure. The device 1100 may be a device for an application and/or a system. For example, the device 1100 may be a vehicle. Alternatively, in various embodiments the device 1100 may be an appliance, consumer electronics, or the like. The device 1100 illustrated may be a system and/or apparatus that includes a processor 1102, memory 1104, communications circuitry 1106, input/output circuitry 1108, battery 1112, battery management system 1114, EIS circuitry 1116, and all of which may be connected by a bus or buses 1110. Various embodiments may also include one or more vehicle systems 1120 or subsystems, such as an on-board charger 1122, traction inverter 1124, aux DC/DC 1126, and the like, which may also be connected by a bus or busses 1110. In various embodiments, pre-charge circuitry may be in one of the vehicle systems 1120. While such connections are illustrated as bus 1110, it will be readily appreciated that there may be multiple other connections.

The processor 1102, although illustrated as a single block, may be comprised of a plurality of components and/or processor circuitry. The processor 1102 may be implemented as, for example, various components comprising one or a plurality of microprocessors with accompanying digital signal processors; one or a plurality of processors without accompanying digital signal processors; one or a plurality of coprocessors; one or a plurality of multi-core processors; processing circuits; and various other processing elements. The processor may include integrated circuits. In various embodiments, the processor 1102 may be configured to execute applications, instructions, and/or programs stored in the processor 1102, memory 1104, or otherwise accessible to the processor 1102. When executed by the processor 1102, these applications, instructions, and/or programs may enable the execution of one or a plurality of the operations and/or functions described herein. Regardless of whether it is configured by hardware, firmware/software methods, or a combination thereof, the processor 1102 may comprise entities capable of executing operations and/or functions according to the embodiments of the present disclosure when correspondingly configured.

The memory 1104 may comprise, for example, a volatile memory, a non-volatile memory, or a certain combination thereof. Although illustrated as a single block, the memory 1104 may comprise a plurality of memory components. In various embodiments, the memory 1104 may comprise, for example, a random access memory, a cache memory, a flash memory, a hard disk, a circuit configured to store information, or a combination thereof. The memory 1104 may be configured to write or store data, information, application programs, instructions, etc. so that the processor 1104 may execute various operations and/or functions according to the embodiments of the present disclosure. For example, in at least some embodiments, a memory 1104 may be configured to buffer or cache data for processing by the processor 1102. Additionally or alternatively, in at least some embodiments, the memory 1104 may be configured to store program instructions for execution by the processor 1102. The memory 1104 may store information in the form of static and/or dynamic information. When the operations and/or functions are executed, the stored information may be stored and/or used by the processor 1102.

The communication circuitry 1106 may be implemented as a circuit, hardware, computer program product, or a combination thereof, which is configured to receive and/or transmit data from/to another component or apparatus. The computer program product may comprise computer-readable program instructions stored on a computer-readable medium (e.g., memory 1104) and executed by a processor 1102. In various embodiments, the communication circuitry 1106 (as with other components discussed herein) may be at least partially implemented as part of the processor 1102 or otherwise controlled by the processor 1102. The communication circuitry 1106 may communicate with the processor 1102, for example, through a bus 1110. Such a bus 1110 may connect to the processor 1102, and it may also connect to one or more other components of the processor 1102. The communication circuitry 1106 may be comprised of, for example, transmitters, receivers, transceivers, network interface cards and/or supporting hardware and/or firmware/software, and may be used for establishing communication with another component(s), apparatus(es), and/or system(s). The communication circuitry 1106 may be configured to receive and/or transmit data that may be stored by, for example, the memory 1104 by using one or more protocols that can be used for communication between components, apparatuses, and/or systems.

The input/output circuitry 1108 may communicate with the processor 1102 to receive instructions input by an operator and/or to provide audible, visual, mechanical, or other outputs to an operator. The input/output circuitry 1108 may comprise supporting devices, such as a keyboard, a mouse, a user interface, a display, a touch screen display, lights (e.g., warning lights), indicators, speakers, and/or other input/output mechanisms. The input/output circuitry 1108 may comprise one or more interfaces to which supporting devices may be connected. In various embodiments, aspects of the input/output circuitry 1108 may be implemented on a device used by the operator to communicate with the processor 1102. The input/output circuitry 1108 may communicate with the memory 1104, the communication circuitry 1106, and/or any other component, for example, through a bus 1110.

A battery 1112 may provide power to the device 1100. In various embodiments, the battery 1112 may be a single battery cell or may be multiple battery cells that form one or more battery packs.

The battery management system 1114 may include EIS circuitry 1116, one or more dedicated processors, one or more dedicated memories, and/or additional electrical components. In various embodiments the EIS circuitry 1116 may be configured as described herein and configured to perform one or more operations as described herein. The EIS circuitry may generate one or more output signals that may be provided to the battery management system 1114 to determine and/or measure an impedance of the battery 1112. In various embodiments, the impedance of the battery 1112 may be determined via a look-up table based on the output signal(s) of the EIS circuitry 1116. This impedance of the battery 1112 may be used by the battery management system 1114 to determine, among other things, a state of health of the battery. The device 1100 may generate or perform one or more operations based on the state of health of the battery 1112, such as cease battery operations, shut down the device 1100, generate, display, and/or transmit a warning message, and the like.

It should be readily appreciated that the embodiments of the systems and apparatuses, described herein may be configured in various additional and alternative manners in addition to those expressly described herein.

### Conclusion

Operations and/or functions of the present disclosure have been described herein, such as in flowcharts. As will be appreciated, computer program instructions may be loaded onto a computer or other programmable apparatus (e.g., hardware) to produce a machine, such that the resulting computer or other programmable apparatus implements the operations and/or functions described in the flowchart blocks herein. These computer program instructions may also be stored in a computer-readable memory that may direct a computer, processor, or other programmable apparatus to operate and/or function in a particular manner, such that the instructions stored in the computer-readable memory produce an article of manufacture, the execution of which implements the operations and/or functions described in the flowchart blocks. The computer program instructions may also be loaded onto a computer, processor, or other programmable apparatus to cause a series of operations to be performed on the computer, processor, or other programmable apparatus to produce a computer-implemented process such that the instructions executed on the computer, processor, or other programmable apparatus provide operations for implementing the functions and/or operations specified in the flowchart blocks. The flowchart blocks support combinations of means for performing the specified operations and/or functions and combinations of operations and/or functions for performing the specified operations and/or functions. It will be understood that one or more blocks of the flowcharts, and combinations of blocks in the flowcharts, can be implemented by special purpose hardware-based computer systems which perform the specified operations and/or functions, or combinations of special purpose hardware with computer instructions.

While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

While operations and/or functions are illustrated in the drawings in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

While this detailed description has set forth some embodiments of the present invention, the appended claims cover other embodiments of the present invention which differ from the described embodiments according to various modifications and improvements.

Within the appended claims, unless the specific term “means for” or “step for” is used within a given claim, it is not intended that the claim be interpreted under 35 U.S.C. § 112, paragraph 6.

1. A system comprising:
at least one battery;
a pre-charge circuitry electrically coupled to a load, wherein the pre-charge circuitry comprises an inverse buck circuitry, wherein the inverse buck circuitry comprises a first capacitor electrically coupled to the load, and wherein the pre-charge circuitry is configured to limit an inrush current during charging of the first capacitor, including charging the first capacitor with a periodic waveform;
an EIS circuitry electrically connected to the pre-charge circuitry to receive the periodic waveform and to transmit the periodic waveform as a stimulus signal to the at least one battery;
wherein the EIS circuitry is further configured to receive a response signal from the at least one battery in response to the stimulus signal; and
wherein the EIS circuitry is further configured to measure an impedance of the battery based on the response signal.

2. The system of claim 1, wherein the stimulus signal is comprised of one or more triangular waveforms.

3. The system of claim 1, wherein the stimulus signal is comprised of at least three phases, including a beginning phase, a central phase, and a final phase, wherein the periodic waveform is different in of the at least three phases.

4. The system of claim 1, wherein the EIS circuitry is configured to receive the periodic waveform during battery charging and battery discharging.

5. The system of claim 1 further comprising a battery management system, wherein the battery management system is configured to generate a state of health of the at least one battery based on the impedance.

6. The system of claim 1, wherein the EIS circuitry is further configured to generate at least one additional signal to superimpose on the periodic waveform of the stimulus signal.

7. The system of claim 6, wherein the at least one additional signal comprises a first frequency that is different from the frequency of the periodic waveform.

8. The system of claim 1, wherein the pre-charge circuitry is located in a traction inverter, an on-board charge, or an auxiliary DC/DC.

9. The system of claim 1, wherein the EIS circuitry is included in an integrated circuit.

10. The system of claim 1, wherein the system is a vehicle.

11. A method comprising:
generate, with a pre-charge circuitry comprising an inverse buck circuitry, a periodic waveform to charge a first capacitor, wherein the pre-charge circuitry is electrically coupled to a load, wherein the inverse buck circuitry comprises the first capacitor electrically coupled to the load, and wherein the pre-charge circuitry is configured to limit an inrush current during charging of the first capacitor;
receiving the periodic waveform at an EIS circuitry;
transmitting, by the EIS circuitry to the at least one battery, the periodic waveform as a stimulus signal;
receiving, at the EIS circuitry from the at least one battery, a response signal based on the stimulus signal; and
measuring an impedance of the at least one battery based on the response signal.

12. The method of claim 11, wherein the stimulus signal is comprised of one or more triangular waveforms.

13. The method of claim 11, wherein the stimulus signal is comprised of at least three phases, including a beginning phase, a central phase, and a final phase, wherein the periodic waveform is different in of the at least three phases.

14. The method of claim 11, wherein receiving the periodic waveform at an EIS circuitry is during battery charging and battery discharging.

15. The method of claim 11 further comprising:
generating, by a battery management system, a state of health of the at least one battery based on the impedance.

16. The method of claim 11 further comprising:
generating, by the EIS circuitry, at least one additional signal to superimpose on the periodic waveform of the stimulus signal.

17. The method of claim 16, wherein the at least one additional signal comprises a first frequency that is different from the frequency of the periodic waveform.

18. The method of claim 11, wherein the pre-charge circuitry is located in a traction inverter, an on-board charge, or an auxiliary DC/DC.

19. The method of claim 11, wherein the EIS circuitry is included in an integrated circuit.

20. The method of claim 11, wherein the pre-charge circuitry, the EIS circuitry, and the at least one battery are in a vehicle.
